(19) United States
(12) Patent Application Publication
(10) Pub. No.: US 2026/0052999 A1
(43) Pub. Date: Feb. 19, 2026

(54) HIGH FREQUENCY MODULE

(71) Applicant: Murata Manufacturing Co., Ltd., Nagaokakyo-shi (JP)

(72) Inventors: Shogo YANASE, Nagaokakyo-shi (JP); Tomomi Yasuda, Nagaokakyo-shi (JP); Minoru Iwanaga, Nagaokakyo-shi (JP); Morio Takeuchi, Nagaokakyo-shi (JP)

(21) Appl. No.: 19/369,507

(22) Filed: Oct. 27, 2025

Related U.S. Application Data
(63) Continuation of application No. PCT/JP2024/015441, filed on Apr. 18, 2024.

(30) Foreign Application Priority Data
May 1, 2023 (JP) 2023-075436
Nov. 30, 2023 (JP) 2023-202580

(51) Int. Cl. H01L 23/552; H01L 23/498; H01L 23/50; H01L 23/00

(52) U.S. Cl. CPC H10W 42/20; H10W 72/00; H10W 90/701; H10W 90/724

(57) ABSTRACT

A high frequency module includes a SAW filter, a substrate over which the SAW filter is mounted, a shield electrode, a ground electrode, and a connection member. The SAW filter has major surfaces opposite to each other and a side surface. The shield electrode covers at least part of the side surface of the SAW filter. The ground electrode is disposed on the substrate, and is connected to a ground potential. The connection member is disposed outside the SAW filter, and electrically connects the shield electrode to the ground electrode.

### CROSS REFERENCE TO RELATED APPLICATIONS

This application is a continuation of International Application No. PCT/JP2024/015441, filed April 18, 2024, which claims priority to Japanese Patent Application No. 2023-202580, filed November 30, 2023, and Japanese Patent Application No. 2023-075436, filed May 1, 2023, the contents of each of which are hereby incorporated by reference in their entirety.

### TECHNICAL FIELD

The present disclosure relates to a high frequency module, and particularly to a technique of shielding between components disposed in a high frequency module.

### BACKGROUND

U.S. Patent Application Publication No. 2014/0308907 (the “’907 Publication”) discloses a configuration in which ground vias that penetrate the inside of a functional component are disposed in the functional component disposed between two electronic components on a substrate of a high frequency module. In the configuration described in the ’907 Publication, these ground vias function as a shield that insulates the two electronic components from each other, and thus electromagnetic interference (EMI) between the electronic components can be suppressed.

A high frequency module like the above-described one is used for, for example, a mobile communication device such as a smartphone or a cellular phone. In such a mobile communication device, demands for reduction in the size and the thickness of the device itself are still high. Further, components mounted inside the device also tend to increase in association with enhancement in functions. Thus, size reduction of the component disposed inside the device like the high frequency module is also required.

The high frequency module possibly includes components that generate electromagnetic noise in association with operation thereof like, for example, an amplifier and a switch. The generated electromagnetic noise possibly becomes a cause of the lowering of performance of another component in the high frequency module and/or another piece of equipment in the communication device.

To address such a problem, in the above-mentioned ’907 Publication, electromagnetic noise is blocked by making the ground vias that penetrate the functional component included in the high frequency module inside this component, and isolation between components in the high frequency module is enhanced.

However, in the configuration disclosed in the ’907 Publication, the ground vias that penetrate the device are required to be made inside the high frequency module. Thus, there is a possibility that the size of the high frequency module itself becomes large due to these ground vias. Therefore, this configuration possibly becomes a cause of inhibition of size reduction of the communication device including the high frequency module.

The present disclosure has been made in order to solve such a problem, and an aspect thereof is to improve characteristics of isolation between components while suppressing increase in the component size in a high frequency module.

### SUMMARY OF THE INVENTION

A high frequency module according to the present disclosure includes a first component, a first substrate over which the first component is mounted, a first shield electrode, a ground electrode, and a connection member. The first component has a first major surface and a second major surface opposite to each other and a side surface that couples the first major surface and the second major surface. The first shield electrode covers at least part of the side surface of the first component. The ground electrode is disposed on the first substrate, and is connected to a ground potential. The connection member is disposed outside the first component, and electrically connects the first shield electrode to the ground electrode.

In the high frequency module according to the present disclosure, the shield electrode is disposed on the outer surface (side surface) of the functional element (first component) mounted over the substrate of the high frequency module. This shield electrode is connected to the ground electrode on the substrate by the connection member. The shield electrode has a flat plate shape, and thus increase in the size of the functional element itself can be suppressed compared with a case in which a via is formed inside the functional element. In addition, this functional element itself can be made to function as a shield between components. Therefore, in the high frequency module, characteristics of isolation between components can be improved while increase in the component size is suppressed.

### BRIEF DESCRIPTION OF DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a sectional view of a high frequency module in accordance with aspects of the present disclosure;

FIG. 2 is a sectional view of a high frequency module in accordance with aspects of the present disclosure;

FIG. 3 is a sectional view of a high frequency module in accordance with aspects of the present disclosure;

FIG. 4 is a sectional view of a high frequency module in accordance with aspects of the present disclosure;

FIG. 5 is a sectional view of a high frequency module in accordance with aspects of the present disclosure;

FIG. 6 is a sectional view of a high frequency module in accordance with aspects of the present disclosure;

FIG. 7 is a sectional view of a high frequency module in accordance with aspects of the present disclosure;

FIG. 8 is a sectional view of a high frequency module in accordance with aspects of the present disclosure;

FIG. 9 is a sectional view of a high frequency module in accordance with aspects of the present disclosure;

FIG. 10 is a sectional view of a high frequency module in accordance with aspects of the present disclosure;

FIG. 11 is a sectional view of a high frequency module in accordance with aspects of the present disclosure; and

FIG. 12 is a sectional view of a high frequency module in accordance with aspects of the present disclosure.

### DETAILED DESCRIPTION OF EMBODIMENTS

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

Aspects of the present disclosure are described in detail below with reference to the drawings. In the drawings, the same or corresponding part is given the same numeral, and description thereof is not repeated.

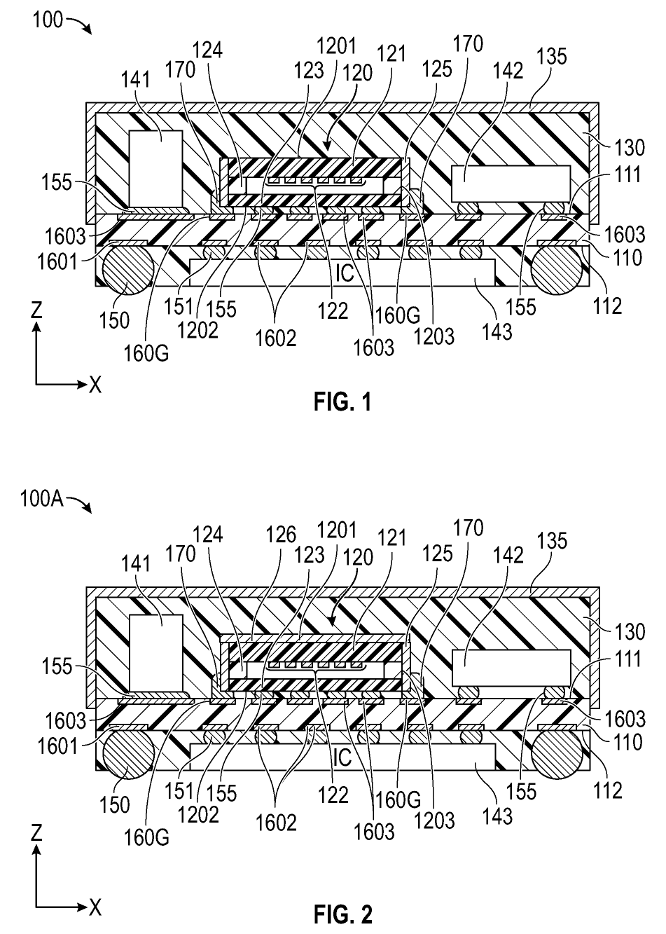

FIG. 1 is a sectional view of a high frequency module 100 according to an aspect of the present disclosure. The high frequency module 100 is used for processing a high frequency signal radiated or received by an antenna in a mobile communication device typified by a cellular phone or a smartphone, for example.

Referring to FIG. 1, the high frequency module 100 includes a dielectric substrate 110 with a flat plate shape and a plurality of functional elements disposed over and under the dielectric substrate 110. In the high frequency module 100 according to the present disclosure, as examples of the functional elements, a filter 120, an inductor 141 for impedance matching, an amplifier 142 for signal amplification, and an integrated circuit (IC) 143 are disposed over and under the dielectric substrate 110. In the following description, the normal direction to a major surface of the dielectric substrate 110 is defined as a Z-axis direction, and a plane parallel to the major surface is defined as an X-Y-plane. Further, the positive direction of the Z-axis is referred to as upward direction and the negative direction is referred to as downward direction in some cases.

In the example of FIG. 1, the filter 120, the inductor 141, and the amplifier 142 are disposed over an upper surface 111 of the dielectric substrate 110. Moreover, under a lower surface 112 of the dielectric substrate 110, the integrated circuit 143 and a connection terminal 150 for connecting the high frequency module 100 to a mounting board (not depicted) are disposed. The connection terminal 150 is, for example, a solder ball.

The dielectric substrate 110 is, for example, a low temperature co-fired ceramics (LTCC) multilayer substrate, a multilayer resin substrate formed by laminating resin layers composed of a resin such as epoxy or polyimide, a multilayer resin substrate formed by laminating resin layers composed of a liquid crystal polymer (LCP) having a lower dielectric constant, a multilayer resin substrate formed by laminating resin layers composed of a fluorine-based resin, a multilayer resin substrate formed by laminating resin layers composed of a polyethylene terephthalate (PET) material, or a ceramics multilayer substrate other than the LTCC multilayer substrate. The dielectric substrate 110 is not necessarily required to have a multilayer structure, and may be a single-layer substrate.

A plurality of electrode pads for mounting each piece of equipment are disposed on the upper surface 111 and the lower surface 112 of the dielectric substrate 110. In FIG. 1, the connection terminal 150 is connected to an electrode pad 1601 of the dielectric substrate 110 at the lower surface 112 of the dielectric substrate 110. Further, the integrated circuit 143 is connected to electrode pads 1602 of the dielectric substrate 110, with solder bumps 151 interposed therebetween.

At the upper surface 111 of the dielectric substrate 110, the filter 120, the inductor 141, and the amplifier 142 are connected to electrode pads 1603 of the dielectric substrate 110, with solder bumps 155 interposed therebetween. As described below, a shield electrode 125 disposed on a side surface of the filter 120 is connected to electrode pads 160G for grounding by connection members 170.

The pieces of equipment mounted over and under the dielectric substrate 110 are sealed by a sealing resin 130. Moreover, a shield electrode 135 is disposed to cover the surface of the sealing resin 130 on the upper side relative to the dielectric substrate 110. The shield electrode 135 is formed of an electrically-conductive member of a metal or the like, and is connected to a ground potential of the mounting board (not depicted) through the connection terminal 150 for grounding. The shield electrode 135 prevents electromagnetic waves generated from the equipment inside the high frequency module 100 from leaking to the external, and eliminates the influence of electromagnetic waves generated in external equipment on the internal equipment.

The inductor 141 is used for impedance matching between pieces of equipment in the high frequency module 100 or between equipment in the high frequency module 100 and external equipment such as an antenna. As equipment for the impedance matching, a capacitor (not depicted) may be disposed instead of or in addition to the inductor 141.

The amplifier 142 is a power amplifier (PA) at the time of signal transmission and/or a low noise amplifier (LNA) for the time of signal reception.

The integrated circuit 143 includes, for example, a power management integrated circuit (PMIC) for power supply control and a radio frequency integrated circuit (RFIC) that executes frequency conversion for transmission and received signals. The RFIC up-converts a baseband signal with an intermediate frequency (IF) to be transmitted from the mounting board to convert the baseband signal to a high frequency signal (radio frequency (RF)) for transmission. The high frequency signal obtained by the conversion is amplified by the PA and is transmitted from an antenna. Further, the RFIC down-converts a high frequency signal received by the antenna to the intermediate frequency. The converted received signal is amplified by the LNA and is output to the mounting board. A low noise amplifier different from the low noise amplifier that forms the amplifier 142 or a switch may be included as the integrated circuit 143.

The filter 120 allows a signal in a specific frequency band to pass therethrough or blocks the signal in the transmission signal or the received signal. The filter 120 is any of a high pass filter, a low pass filter, and a band pass filter. Moreover, the filter 120 may be a combination of filters, and may be, for example, a duplexer and a multiplexer that extract signals in different frequency bands from a received signal and output the signals.

In an aspect of the disclosure, a description is given by taking a surface acoustic wave (SAW) filter using a SAW resonator as an example of the filter 120. However, the filter 120 may be another acoustic wave filter using a bulk acoustic wave (BAW) resonator such as a film bulk acoustic resonator (FBAR) and/or a solid mounted resonator (SMR), or may be an LC filter composed of an inductor and a capacitor.

The filter 120 includes a piezoelectric substrate 121, a resonator 122, a cover member 123, a support layer 124, and the shield electrode 125.

The piezoelectric substrate 121 is formed of, for example, a piezoelectric single crystal material such as lithium tantalate (LiTaO₃), lithium niobate (LiNbO₃), zinc oxide (ZnO), aluminum nitride, or lead zirconate titanate (PZT), or a piezoelectric multilayer material of them. The resonator 122 is disposed on the major surface on the side of the lower surface 112 in the piezoelectric substrate 121. The resonator 122 includes an acoustic wave resonator composed of two opposite comb-shaped interdigital transducer (IDT) electrodes. A SAW resonator is formed by the piezoelectric substrate 121 and the resonator 122.

The resonator 122 can be formed by using an elemental metal composed of at least one kind of metal among aluminum (Al), copper (Cu), silver (Ag), gold (Au), titanium (Ti), tungsten (W), platinum (Pt), chromium (Cr), nickel (Ni), and molybdenum (Mo), or a metal material such as an alloy composed mainly of them. Further, the resonator 122 may have a structure obtained by laminating metal films composed of these metals or alloys.

The cover member 123 is supported at a position separate from the piezoelectric substrate 121 by the support layer 124. The support layer 124 is disposed to surround the periphery of the resonator 122 on the piezoelectric substrate 121. A hollow space is formed between the piezoelectric substrate 121 and the cover member 123 by the piezoelectric substrate 121, the cover member 123, and the support layer 124. The cover member 123 and the support layer 124 are formed of, for example, a resin containing an organic material, such as polyimide, epoxy-based resin, cyclic olefin-based resin, benzocyclobutene, polybenzoxazole, phenol-based resin, silicone, or acrylic resin, or an electrically-conductive material such as copper, silver, aluminum, nickel, or an alloy of them.

An upper surface 1201, a lower surface 1202, and a side surface 1203 of the filter 120 are formed by the piezoelectric substrate 121, the cover member 123, and the support layer 124. A wiring layer that is not depicted is formed on the lower surface 1202 of the filter 120, and a signal path in this wiring layer is connected to the electrode pad 1603 of the dielectric substrate 110 through the solder bump 155.

The shield electrode 125 that is formed of an electrically-conductive member of, for example, copper or the like and has a flat plate shape is disposed on at least part of the side surface 1203 of the filter 120. The shield electrode 125 may be directly connected to the electrode pads 160G of the dielectric substrate 110 by the connection members 170 such as a solder. At least part of the connection member 170 overlaps with the shield electrode 125 as viewed in plan view from the normal direction to the upper surface 1201 of the filter 120. That is, directly under the shield electrode 125, the connection member 170 connects the shield electrode 125 to the electrode pad 160G.

As described above, in the high frequency module, a plurality of functional elements are disposed on the same dielectric substrate in general. The functional elements include a component that generates electromagnetic noise in association with operation thereof like an amplifier or a switch in some cases. The generated electromagnetic noise possibly becomes a cause of affecting another component in the high frequency module and/or another piece of equipment different from the high frequency module in a communication device and lowering the communication quality and the equipment performance.

In the high frequency module 100 described above, the shield electrode 125 is disposed on the side surface of the filter 120. Thus, by being disposed between other functional elements as depicted in FIG. 1, the filter 120 is allowed to function as a shield that blocks electromagnetic noise between these functional elements. Moreover, the influence on the resonator 122 in the filter 120 can also be reduced. Due to this, in the high frequency module, the lowering of the communication quality and the equipment performance attributed to the electromagnetic noise can be suppressed, and characteristics of isolation between components can be improved.

Here, in the high frequency module 100, as described above, the shield electrode 125 that is the flat plate electrode disposed on the side surface of the filter 120 is connected to the electrode pads 160G (ground electrodes) on the dielectric substrate 110 by the connection members 170 disposed directly under the shield electrode 125. By forming the shield electrode 125 into a thin flat plate shape and disposing the shield electrode 125 on the outer surface of the filter 120, the filter 120 itself can be made to function as a shield while increase in the component size of the filter 120 is suppressed compared with a case in which a via inside the filter is used as the shield as in the above-described ’907 Publication.

Further, when the connection distance between the shield electrode 125 and the electrode pad 160G becomes long, an inductance component attributed to the connection member becomes large and the shield characteristics possibly lower. In the high frequency module 100 as described above, because the shield electrode 125 is connected to the electrode pads 160G by the connection members 170 directly under the shield electrode 125, the distance between the shield electrode 125 and the electrode pad 160G can be set to the shortest distance, and the inductance component of the connection member 170 can be made as small as possible. Therefore, the lowering of the shield characteristics attributed to the connection distance between the shield electrode 125 and the electrode pad 160G can be minimized.

In another arrangement, the shield electrode 125 is disposed on the whole of the side surface of the filter 120 in order to improve the shield effect provided by the shield electrode 125. Moreover, a copper or stainless steel member or the like may be used as the material of the shield electrode 125. Further, in the above description, the example of the case in which the functional element on which the shield electrode is disposed is the filter has been described. However, a case in which another piece of equipment such as an amplifier and/or an IC has the shield electrode is also possible.

“Filter 120” as described above corresponds to “first component” in the present disclosure. “Upper surface 1201” and “lower surface 1202” as described above correspond to “first major surface” and “second major surface,” respectively, in the present disclosure. “Dielectric substrate 110” as described above corresponds to “first substrate” in the present disclosure. “Shield electrode 125” as described above corresponds to “first shield electrode” in the present disclosure. “Electrode pad 160G” as described above corresponds to “ground electrode” in the present disclosure.

In another aspect, a configuration in which a shield electrode is disposed also on the upper surface 1201 of the filter 120 is described.

FIG. 2 is a sectional view of a high frequency module 100A of another aspect of the disclosure. In the high frequency module 100A, a shield electrode 126 is disposed to cover the whole of the upper surface 1201 in addition to the side surface 1203 of the filter 120. The shield electrode 126 is connected, at an end portion thereof, to the shield electrode 125 disposed on the side surface 1203. The other configuration in FIG. 2 is the same as that in FIG. 1, and description of elements that overlap with those in FIG. 1 is not repeated.

By covering the whole of the upper surface 1201 and the side surface 1203 of the filter 120 by the shield electrodes 125 and 126 in this manner, for example, the influence of electromagnetic noise coming from the upper surface 1201 of the filter 120 can be eliminated.

According to an exemplary aspect, “shield electrodes 125 and 126” as described above correspond to “first shield electrode” in the present disclosure.

In another aspect of the disclosure, another form of the connection between the shield electrode and the ground electrode is described.

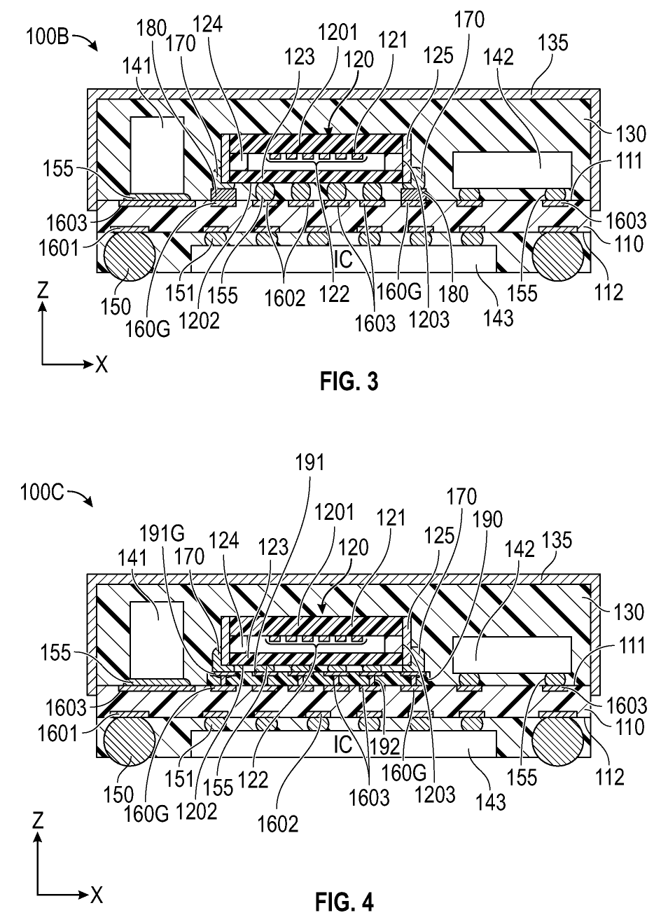

FIG. 3 is a sectional view of a high frequency module 100B the aspect described above. The high frequency module 100B has a configuration obtained by adding protruding electrodes 180 to the high frequency module 100 of FIG. 1. The protruding electrode 180 is disposed between the connection member 170 and the electrode pad 160G in such a manner as to protrude in the Z-axis direction from the electrode pad 160G. In other words, the connection member 170 is connected to the electrode pad 160G, with the protruding electrode 180 interposed therebetween.

The protruding electrodes 180 are formed by disposing a metal member on the electrode pads 160G by, for example, plating or sputtering before mounting of the filter 120. Alternatively, the protruding electrodes 180 may be formed by connecting columnar electrodes onto the electrode pads 160G.

By connecting the shield electrode 125 of the filter 120 to the protruding electrodes 180 disposed on the electrode pads 160G by the connection members 170 in this manner, the position of the upper surface 1201 of the filter 120 can be made higher than that in the case of the high frequency module 100 the aspect described above. This can enhance the shield effect provided by the filter 120 in a case in which a component with a comparatively large mounting dimension in the Z-axis direction is used.

In a case in which the installation position of the filter 120 is made high by only the solder of the connection member 170 without disposing the protruding electrode 180, the interval between components is possibly required to be widened in view of spreading of the molten solder in the mounting surface direction in a step of reflow. In this case, the disposition area of the components becomes large, which leads to increase in the component size. Thus, by disposing the protruding electrode 180, the spreading of the solder in the reflow can be suppressed, and the increase in the component size can be suppressed.

Although the protruding electrodes 180 are disposed only between the connection member 170 and the electrode pad 160G in FIG. 3, the protruding electrode 180 may be disposed also between the filter 120 and the electrode pad 1603 on the dielectric substrate 110.

In another aspect of the disclosure, still another form of the connection between the shield electrode and the ground electrode is described.

FIG. 4 is a sectional view of a high frequency module 100C in accordance with an aspect of the disclosure. The high frequency module 100C has a configuration obtained by adding an intermediate substrate 190 to the high frequency module 100 of FIG. 1. The intermediate substrate 190 is disposed between the filter 120 and the dielectric substrate 110, and electrode pads 191 and 191G are disposed on a mounting surface of the intermediate substrate 190. The electrode pads 191 are connected to the electrode pads 1603 on the dielectric substrate 110 by vias 192 disposed inside the intermediate substrate 190, and the electrode pads 191G are connected to the electrode pads 160G by the vias 192. Although the intermediate substrate 190 is depicted as a separate body from the dielectric substrate 110 in FIG. 4, the intermediate substrate 190 may be a substrate shaped monolithically with the dielectric substrate 110 by using the same material.

The filter 120 is connected to the electrode pads 191 of the intermediate substrate 190, with the solder bumps 155 interposed therebetween. Further, the shield electrode 125 is connected to the electrode pads 191G of the intermediate substrate 190, with the connection members 170 interposed therebetween.

By disposing the filter 120 over the dielectric substrate 110, with the intermediate substrate 190 interposed therebetween, in this manner, the position of the upper surface 1201 of the filter 120 can be made higher than that in the case of the high frequency module 100 of as described above. This can enhance the shield effect provided by the filter 120 in a case in which a component with a comparatively large mounting dimension in the Z-axis direction is used.

According to an exemplary aspect, “intermediate substrate 190” described above corresponds to “second substrate” in the present disclosure. “Via 192” described above corresponds to “through-electrode” in the present disclosure.

In accordance with an aspect described below, a description is given of a configuration in which the shield electrode 125 of the filter 120 is connected to the electrode pad 160G of the dielectric substrate 110 by using a bonding wire.

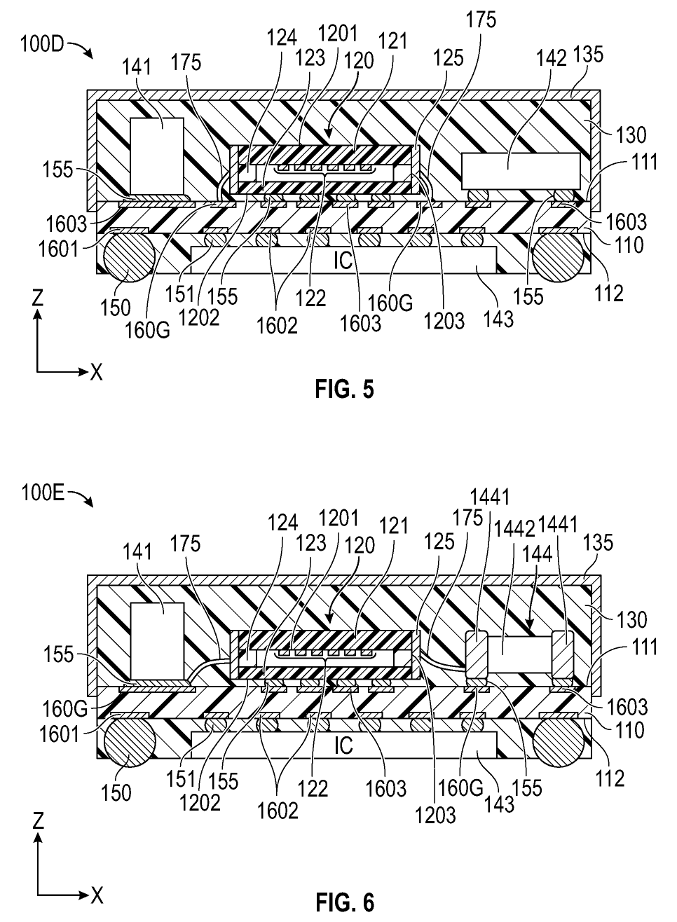

FIG. 5 is a sectional view of a high frequency module 100D according to an aspect of the disclosure. In the high frequency module 100D, the connection members 170 in FIG. 1 are replaced by bonding wires 175, and the shield electrode 125 is connected to the electrode pads 160G by the bonding wires 175. The other configuration is similar to that in the high frequency module 100 of an aspect depicted in FIG. 1, and description of elements that overlap with those in FIG. 1 is not repeated.

Also in such a configuration, the filter 120 can be made to function as a shield between components by disposing the filter 120 with the side surface on which the shield electrode 125 is disposed between other functional elements over the dielectric substrate 110. Therefore, in the high frequency module, the lowering of the communication quality and the equipment performance attributed to electromagnetic noise can be suppressed, and characteristics of isolation between components can be improved.

According to an exemplary aspect, “bonding wire 175” described above corresponds to “connection member” in the present disclosure.

In accordance with an aspect of the disclosure , a description is given of a configuration in which the shield electrode is connected, by a bonding wire, to a ground electrode to which another functional element over the dielectric substrate 110 is connected.

FIG. 6 is a sectional view of a high frequency module 100E in accordance with an aspect of the disclosure. The high frequency module 100E of FIG. 6 has a configuration in which a capacitor 144 is disposed instead of the amplifier 142 as a functional element. The amplifier 142 may be disposed also in the high frequency module 100E.

The capacitor 144 includes a main portion 1442 and connection terminals 1441 each disposed at a respective one of both ends of this main portion 1442. The capacitor 144 in the example of the high frequency module 100E is a shunt capacitor connected to the ground potential. One connection terminal 1441 is connected to the electrode pad 160G on the dielectric substrate 110 by the solder bump 155. The other connection terminal 1441 is connected to the electrode pad 1603 by the solder bump 155.

Moreover, the inductor 141 is also a shunt inductor connected to the ground potential, and one terminal is connected to the electrode pad 160G by the solder bump 155.

Further, the shield electrode 125 disposed on the side surface of the filter 120 is connected, by the bonding wires 175, to the electrode pads 160G to which the inductor 141 and the capacitor 144 are connected. The bonding wires 175 may be directly connected to the electrode pads 160G, or may be connected to the connection terminal of the inductor 141 and/or the capacitor 144.

In this manner, by using the bonding wire, the shield electrode of the filter can be connected to the ground electrode to which another functional element is connected. Thus, the ground electrode for this shield electrode is not required to be disposed on the dielectric substrate. This can save the mounting area on the dielectric substrate, and thus contribute to size reduction.

According to an exemplary aspect, “capacitor 144” and “inductor 141” described above correspond to “second component” in the present disclosure.

In an aspect of the disclosure described below, a description is given of a configuration having a stacking structure in which another functional element is disposed on the side of the upper surface 1201 of the filter 120.

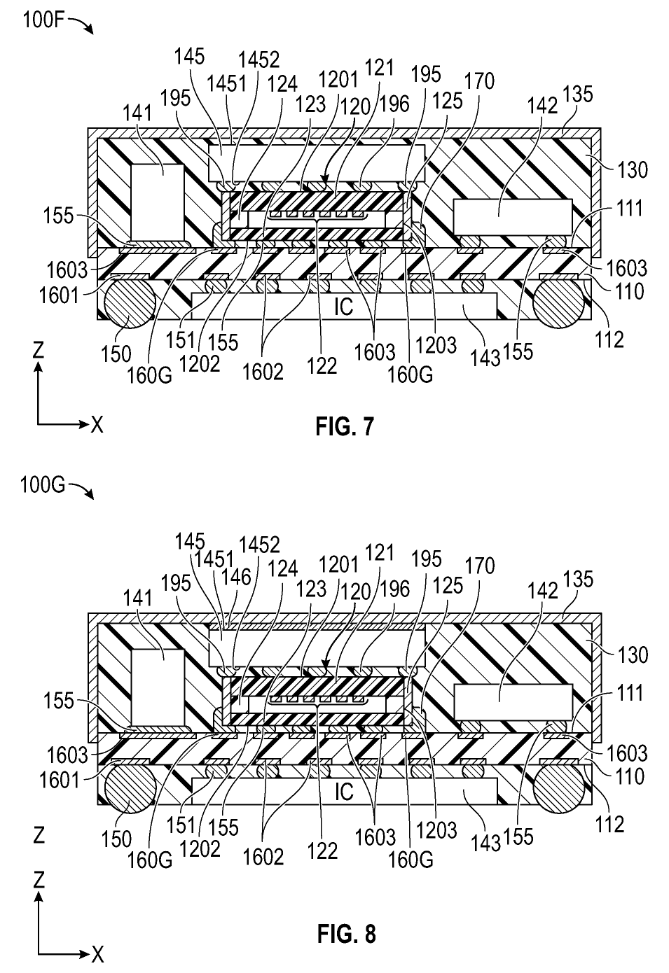

FIG. 7 is a sectional view of a high frequency module 100F according to an aspect of the disclosure. The high frequency module 100F has a configuration obtained by adding another functional element 145 to the high frequency module 100 of an aspect depicted in FIG. 1.

The functional element 145 is an amplifier, an IC, or another filter different from the filter 120. The functional element 145 has an upper surface 1451 and a lower surface 1452, and the lower surface 1452 is disposed opposite to the upper surface 1201 of the filter 120. Moreover, a terminal for grounding in the functional element 145 is connected to the shield electrode 125 of the filter 120 by using a solder bump 195. A signal line and a power supply line in the functional element 145 are connected to the filter 120 by using a solder bump 196, and pass through a path (for example, via) that is not depicted in the filter 120 to be connected to the electrode pad 1603 of the dielectric substrate 110.

By disposing another functional element over the filter with the side surface on which the shield electrode is disposed in this manner, the mounting area on the dielectric substrate can be reduced. This can contribute to size reduction of the equipment.

Further, by disposing a shield electrode also on a side surface of the functional element 145 similarly to the filter 120, characteristics of isolation between components over the dielectric substrate 110 can be further improved. In this case, by connecting the shield electrode of the functional element 145 to the electrode pad 160G of the dielectric substrate 110 through the shield electrode 125 of the filter 120, the connection distance to the ground electrode can be made short, and grounding characteristics of the functional element 145 can be improved.

According to an exemplary aspect, “functional element 145” as described above corresponds to “third component” in the present disclosure. “Upper surface 1451” and “lower surface 1452” as described above correspond to “third major surface” and “fourth major surface,” respectively, in the present disclosure.

In an aspect of the disclosure, a description is given of a configuration that improves heat dissipation characteristics of the functional element 145 of the high frequency module 100F described above.

FIG. 8 is a sectional view of a high frequency module 100G in accordance with an aspect of the disclosure. The high frequency module 100G has a configuration obtained by adding a flat plate electrode 146 to the high frequency module 100F of FIG. 7. Description of elements that overlap with those in FIG. 7 is not repeated with FIG. 8.

The flat plate electrode 146 is disposed to cover at least part of the upper surface 1451 of the functional element 145 and is in contact with also the shield electrode 135 that covers the sealing resin 130. The flat plate electrode 146 is formed of a material with comparatively high thermal conductivity, such as a metal member of copper, aluminum, or the like.

When the functional element 145 is a component that generates heat like an amplifier or an IC, the shield electrode 135 that covers the outer surface of the high frequency module can be made to function as a heat sink by using such a flat plate electrode 146 and bringing the flat plate electrode 146 into contact with this shield electrode 135. This can improve the heat dissipation characteristics of the functional element 145.

The flat plate electrode 146 is not necessarily required to be composed of a metal having electrical conductivity as long as the thermal conductivity thereof is high. However, using a metal material allows this flat plate electrode 146 to double as an electrode for grounding.

According to an exemplary aspect, “shield electrode 135” described above correspond to “second shield electrode” in the present disclosure.

In accordance with an aspect of the disclosure, a description is given of a variation of the connection form between a shield electrode and a ground electrode in a high frequency module that has a stacking configuration and has the shield electrode disposed on a side surface of a functional element on the upper side.

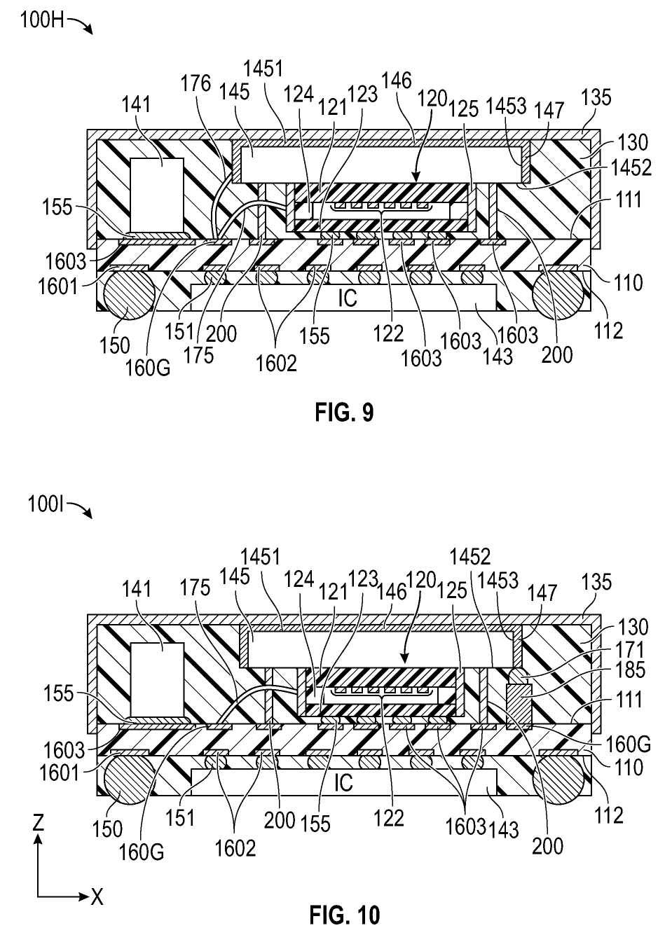

FIG. 9 is a sectional view of a high frequency module 100H in accordance with an aspect of the disclosure. The high frequency module 100H has a configuration in which the dimension in the X-axis direction concerning the functional element 145 in the high frequency module 100G of FIG. 8 is larger than that of the filter 120 and a shield electrode 147 is disposed on a side surface 1453 of the functional element 145. The amplifier 142 is omitted in the high frequency module 100H.

The shield electrode 147 in the functional element 145 is connected to the electrode pad 160G on the dielectric substrate 110 by a bonding wire 176. Moreover, a signal line and a power supply line in the functional element 145 are connected to the electrode pad 1603 on the dielectric substrate 110 by a columnar electrode 200. The shield electrode 125 of the filter 120 is connected to the electrode pad 160G by the bonding wire 175.

When dimensions of the stacked functional elements are different from each other as described above, the connection distance to the ground electrode can be made short by individually connecting the shield electrode in each functional element to the ground electrode.

The connection between the shield electrode 147 of the functional element 145 and the electrode pad 160G may be implemented by using a protruding electrode 185 and a connection member 171 as in a high frequency module 100I of FIG. 10.

Further, in FIGS. 9 and 10, the shield electrode 125 of the filter 120 may be connected to the electrode pad 160G by the connection member 170 like a solder similarly to FIG. 1.

In accordance with an aspect of the disclosure, a description is given of a configuration in which the shield electrode 125 on the side surface of the filter 120 is connected by solder to an external terminal connected to a ground electrode in another functional element over the dielectric substrate 110.

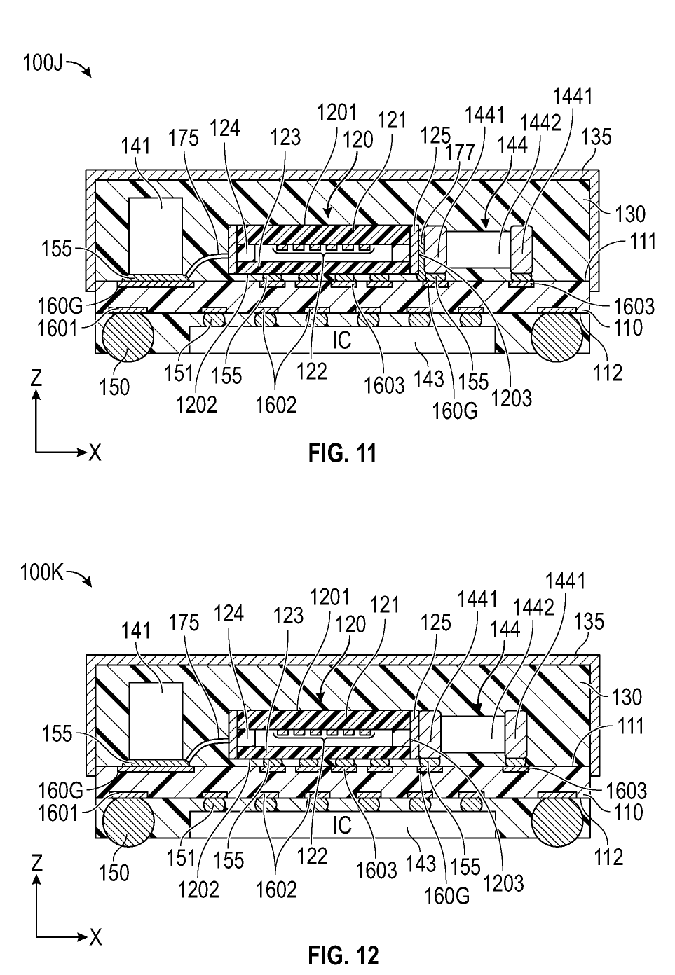

FIG. 11 is a sectional view of a high frequency module 100J in accordance with an aspect of the disclosure. The high frequency module 100J in accordance with an aspect of the disclosure has a configuration in which the capacitor 144 that is a functional element in the high frequency module 100E depicted in FIG. 6 is disposed closer to the filter device 120 and the external terminal 1441 thereof is connected to the shield electrode 125 by a solder 177. The other configuration in FIG. 11 is similar to that in FIG. 6, and description of elements that overlap with those in FIG. 6 is not repeated.

In the high frequency module 100J, substantially the whole of the side surface of the external terminal 1441 is connected to the shield electrode 125 by using the solder 177. At this time, the solder 177 is connected also to the electrode pad 160G for grounding of the capacitor 144 and is disposed to close a gap under the lower surface of the filter 120.

In this manner, the shield electrode 125 is connected to the external terminal 144 across a large area and is connected to electrode pad 160G for grounding across the minimum distance. This can enhance the shield effect provided by the shield electrode, and thus improve isolation between the filter device 120 and the capacitor 144.

For such a configuration, a metal layer based on the solder 177 is made to adhere to the shield electrode 125 of the filter 120 by sputtering. This allows the electrodes to be electrically connected through melting of the solder 177 in reflow. Thus, the configuration can be implemented by a comparatively easy manufacturing method.

Although the description has been given by taking the capacitor 144 as an example of the functional element connected to the shield electrode 125 in accordance with an aspect of the disclosure, an element other than the capacitor may be employed as long as it is equipment with a side surface on which a connection terminal is disposed. Moreover, in FIG. 11, the inductor 141 is connected to the shield electrode 125 by the bonding wire 175. However, the inductor 141 may be connected to the shield electrode 125 through a wiring layer disposed inside the dielectric substrate 110 as described above.

According to an exemplary aspect, “capacitor 144” described above corresponds to “second component” in the present disclosure. Further, “solder 177” as described corresponds to “connection member” in the present disclosure.

In accordance with an aspect of the disclosure, a description is given of a configuration in which the shield electrode 125 on the side surface of the filter 120 is brought into direct contact with an external terminal of another functional element over the dielectric substrate 110.

FIG. 12 is a sectional view of a high frequency module 100K in accordance with an aspect of the disclosure. In the high frequency module 100K, the capacitor 144 is disposed closer to the filter 120 than the capacitor 144 in the case of FIG. 11 over the dielectric substrate 110, and the external terminal 1441 of the capacitor 144 is in direct contact with the shield electrode 125 without the interposition of a connection member such as a solder therebetween. The other configuration in FIG. 12 is similar to that in FIG. 6, and description of elements that overlap with those in FIG. 6 is not repeated.

In such a configuration, the components are disposed to be in direct contact with each other. Thus, the mounting density of the components on the dielectric substrate 110 can be enhanced. Therefore, the size of the high frequency module can be reduced.

It is desirable to bring the shield electrode 125 into contact with the external terminal 144 across as large an area as possible in order to reduce the contact resistance. However, the whole of the side surface of the external terminal 144 is not necessarily required to be in contact with the shield electrode 125. It is sufficient that at least part of the side surface of the external terminal 144 be in contact with the shield electrode 125 to allow establishment of an electrical connection.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

### DESCRIPTION OF REFERENCE SYMBOLS

100, 100A to 100K high frequency module

110 dielectric substrate

111, 1201, 1451 upper surface

112, 1202, 1452 lower surface

120 filter

1203, 1453 side surface

121 piezoelectric substrate

122 resonator

123 cover member

124 support layer

125, 126, 135, 147 shield electrode

130 sealing resin

141 inductor

142 amplifier

143 integrated circuit

144 capacitor

1442 main portion

145 functional element

146 flat plate electrode

150, 1441 connection terminal

151, 155, 195, 196 solder bump

160, 160G, 191, 191G, 1601 to 1603 electrode pad

170, 171 connection member

175, 176 bonding wire

177 solder

180, 185 protruding electrode

190 intermediate substrate

192 via

200 columnar electrode

What is claimed is:

1. A high frequency module comprising:
a first component including a first major surface and a second major surface opposite to each other, and a side surface that couples the first major surface to the second major surface;
a first substrate on which the first component is mounted;
a first shield electrode configured to cover at least a portion of the side surface of the first component;
a ground electrode disposed on the first substrate and connected to a ground potential; and
a connection member disposed outside the first component and that electrically connects the first shield electrode to the ground electrode.

2. The high frequency module according to claim 1, wherein a portion of the connection member overlaps with the first shield electrode in a plan view from a normal direction to the first major surface.

3. The high frequency module according to claim 2, wherein the first shield electrode is directly connected to the ground electrode by the connection member.

4. The high frequency module according to claim 2, further comprising:
a protruding electrode that is connected to the ground electrode and protrudes from the ground electrode in a direction toward the first component,
wherein the first shield electrode is connected to the protruding electrode by the connection member.

5. The high frequency module according to claim 1, further comprising:
a second substrate disposed between the first component and the first substrate,
wherein the second substrate includes a through-electrode that is connected to the ground electrode and penetrates the second substrate, and
the first shield electrode is connected to the through-electrode by the connection member.

6. The high frequency module according to claim 1, further comprising:
a second component disposed over the first substrate,
wherein the ground electrode is connected to a connection terminal of the second component, and
the first shield electrode is connected to the connection terminal by the connection member.

7. The high frequency module according to claim 1, wherein the connection member is a solder.

8. The high frequency module according to claim 1, wherein the connection member is a bonding wire.

9. The high frequency module according to claim 1, further comprising:
a second component disposed over the first substrate,
wherein the ground electrode is connected to a connection terminal of the second component, and at least part of the first shield electrode is in contact with the connection terminal.

10. The high frequency module according claim 1, further comprising:
a third component including a third major surface and a fourth major surface opposite to each other and disposed on the first component such that the fourth major surface is opposite to the first major surface.

11. The high frequency module according to claim 10, further comprising:
a flat plate electrode disposed to cover a portion of the third major surface; and
a second shield electrode disposed to cover components mounted in the high frequency module,
wherein the flat plate electrode is in contact with the second shield electrode.

12. The high frequency module according to claim 1, wherein the first component includes a surface acoustic wave device.

13. The high frequency module according to claim 1, wherein the first component comprises an integrated circuit or an amplifier.

14. The high frequency module according to claim 1, wherein the first component has a rectangular parallelepiped shape, and the first shield electrode is disposed to entirely cover the side surface of the first component.

15. The high frequency module according to claim 1, wherein the first component is disposed such that the second major surface is opposite to the first substrate, and
the first shield electrode is disposed to entirely cover the first major surface and the side surface of the first component.

16. A high frequency module comprising:
a first component including a first major surface and a second major surface opposite to each other, and a side surface that couples the first major surface to the second major surface;
a first substrate on which the first component is mounted;
a first shield electrode configured to cover at least a portion of the side surface of the first component;
a ground electrode disposed on the first substrate and connected to a ground potential;
a third component including a third major surface and a fourth major surface opposite to each other and disposed on the first component such that the fourth major surface is opposite to the first major surface;
a flat plate electrode disposed to cover a portion of the third major surface; and
a second shield electrode disposed to cover components mounted in the high frequency module.

17. The high frequency module according to claim 16, further comprising a connection member disposed outside the first component and that electrically connects the first shield electrode to the ground electrode.

18. The high frequency module according to claim 17, wherein the flat plate electrode is in contact with the second shield electrode.

19. The high frequency module according to claim 17, wherein the connection member is a bonding wire.

20. The high frequency module according to claim 17, wherein a portion of the connection member overlaps with the first shield electrode as viewed in plan view from a normal direction to the first major surface.
